(19) United States
(12) Patent Application Publication
(10) Pub. No.: US 2011/0240965 A1
(43) Pub. Date: Oct. 6, 2011

(54) ORGANIC LIGHT-EMITTING DEVICE

(75) Inventors: Ji-Hwan Yoon, Yongin-City (KR); Ja-Hyun Im, Yongin-City (KR)

(73) Assignee: SAMSUNG MOBILE DISPLAY CO., LTD., Yongin-City (KR)

(21) Appl. No.: 12/979,538

(22) Filed: Dec. 28, 2010

(30) Foreign Application Priority Data
Apr. 1, 2010 (KR) 10-2010-0029989

(51) Int. Cl. H01L 51/52; H01L 51/54

(52) U.S. Cl. 257/40; 257/E51.022; 257/E51.026

(57) ABSTRACT

An organic light-emitting device including an emission layer including one or more emission layer of a red emission layer patterned in a red light-emitting region and a green emission layer patterned in a green light-emitting region and a blue emission layer formed as a common layer, wherein a blue emission is prevented in at least one region of the red light-emitting region and the green light-emitting region by adjusting the HOMO and LUMO levels of a host and a dopant of the green emission layer and/or the red emission layer.

### RELATED APPLICATIONS AND CLAIM OF PRIORITY

This application claims the benefit of Korean Patent Application No. 10-2010-0029989, filed on Apr. 1, 2010, in the Korean Intellectual Property Office, the disclosure of which is incorporated herein in its entirety by reference.

### BACKGROUND

1. Field

One or more embodiments of the present invention relate to an organic light-emitting device.

2. Description of the Related Art

Organic light-emitting devices include a pair of electrodes, including a hole injection electrode and an electron injection electrode, and an organic layer interposed between the electrodes, wherein, when a current is supplied to the electrodes, holes and electrons injected through the hole injection electrode and the electron injection electron, respectively, are re-combined in the organic layer, thereby emitting light. Accordingly, organic light-emitting devices are self-emitting devices. Organic light-emitting devices are lightweight, and can be easily manufactured using a relatively small number of components. In addition, organic light emitting devices provide high-quality images and have wide viewing angles. Furthermore, organic light-emitting devices provide high color purity, accurately realize moving pictures, have low power consumption, and are operated at low voltage. Due to these characteristics, organic light-emitting devices are suitable for mobile electronic devices.

In general, an organic light-emitting device includes a structure of substrate/hole injection electrode/organic layer/electron injection electrode, wherein the organic layer may include at least one layer selected from the group consisting of a hole injection layer, a hole transport layer, an emission layer, a hole blocking layer, an electron transport layer and an electron injection layer.

In order to provide a full-color organic light-emitting display device, for example, the organic layer is patterned in a red light-emitting region, a green light-emitting region, and a blue light-emitting region so as to enable red emission, green emission, and blue emission. In this regard, when a blue emission layer for blue emission is formed as a common layer, the blue light-emitting region may not be needed to be fine-patterned.

In an organic light-emitting device including one or more emission layer of a red emission layer patterned in the red light-emitting region and a green emission layer patterned in the green light-emitting region and the blue emission layer formed as a common layer, the blue emission layer is laid in at least one region of the red light-emitting region and the green light-emitting region, in addition to a blue light-emitting region. Thus, color purity of red emission and green emission may be degraded.

### SUMMARY

One or more embodiments of the present invention include an organic light-emitting device including a substrate; a pair of electrodes on the substrate, the pair of electrodes including a hole injection electrode and an electron injection electrode; and an emission layer interposed between the pair of electrodes, the emission layer including at least one of a red emission layer patterned in a red light-emitting region and a green emission layer patterned in a green light-emitting region and a blue emission layer formed as a common layer covering the at least one of the red emission layer and the green emission layer and a blue light-emitting region, the blue emission layer positioned between the electron injection electrode and said at least one of the red emission layer and the green emission layer; wherein, when the emission layer includes the red emission layer, the red emission layer includes a first host and a first dopant, a highest occupied molecular orbital (HOMO) level of the first host is lower than a highest occupied molecular orbital (HOMO) level of the first dopant, and a lowest occupied molecular orbital (LUMO) level of the first host is lower than a lowest occupied molecular orbital (LUMO) level of the first dopant; and, when the emission layer includes the red emission layer, the green emission layer includes a second host and a second dopant, a highest occupied molecular orbital (HOMO) level of the second host is lower than a highest occupied molecular orbital (HOMO) level of the second dopant, and a lowest occupied molecular orbital (LUMO) level of the second host is lower than a lowest occupied molecular orbital (LUMO) level of the second dopant.

According to an aspect of one or more embodiments, a difference between the HOMO level of the first host and the HOMO level of the first dopant is at least 0.1 eV.

According to an aspect of one or more embodiments, a difference between the LUMO level of the first host and the LUMO level of the first dopant is at least 0.1 eV.

According to an aspect of one or more embodiments, a difference between the HOMO level of the second host and the HOMO level of the second dopant is at least 0.1 eV.

According to an aspect of one or more embodiments, a difference between the LUMO level of the second host and the LUMO level of the second dopant is at least 0.1 eV.

According to an aspect of one or more embodiments, an organic light-emitting device, including: a substrate; a pair of electrodes on the substrate, the pair of electrodes including a hole injection electrode and an electron injection electrode; and an emission layer interposed between the pair of electrodes, the emission layer including: a red emission layer patterned in a red light-emitting region, the red emission layer including a first host and a first dopant, a highest occupied molecular orbital (HOMO) level of the first host being lower than a highest occupied molecular orbital (HOMO) level of the first dopant, a lowest occupied molecular orbital (LUMO) level of the first host being lower than a lowest occupied molecular orbital (LUMO) level of the first dopant; a green emission layer patterned in a green light-emitting region, the green emission layer including a second host and a second dopant, a highest occupied molecular orbital (HOMO) level of the second host being lower than a highest occupied molecular orbital (HOMO) level of the second dopant, and a lowest occupied molecular orbital (LUMO) level of the second host being lower than a lowest occupied molecular orbital (LUMO) level of the second dopant; and a blue emission layer formed as a common layer covering the red emission layer and the green emission layer and a blue light-emitting region.

### BRIEF DESCRIPTION OF THE DRAWINGS

These and/or other aspects will become apparent and more readily appreciated from the following description of the embodiments, taken in conjunction with the accompanying drawings of which:

FIG. 1 is a schematic sectional view of an organic light-emitting device (OLED) according to an embodiment of the present invention;

FIG. 2 illustrates a schematic energy diagram of an organic layer of an organic light-emitting device according to an embodiment of the present invention; and

FIG. 3 illustrates a schematic energy diagram of an organic layer of an organic light-emitting device according to an embodiment of the present invention.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

In the drawings, the thickness of layers, films, etc., are exaggerated for clarity. In the drawings, the thicknesses of some layers and areas are exaggerated for convenience of explanation. It will be understood that when an element such as a layer, film, region, or substrate is referred to as being “on” another element, it can be directly on the other element or intervening elements may also be present.

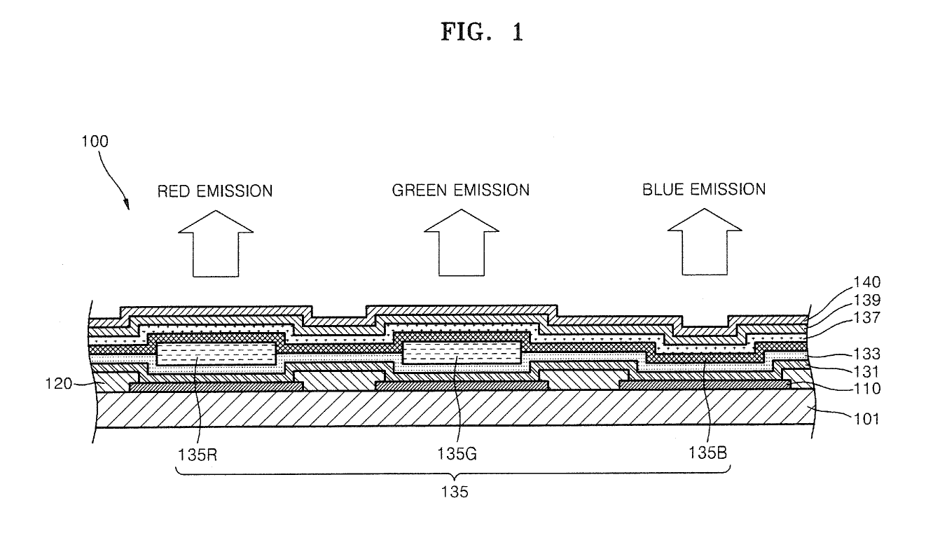

FIG. 1 is a schematic sectional view of an organic light emitting device (OLED) 100 according to an embodiment of the present invention.

The organic light-emitting device 100 includes a substrate 101, a hole injection electrode 110, a hole injection layer 131, a hole transport layer 133, an emission layer 135, an electron transport layer 137, an electron injection layer 139, and an electron injection electrode 140.

The substrate 100, which may be any substrate that is used in conventional organic light-emitting devices, may be a glass substrate or a transparent plastic substrate with excellent mechanical strength, thermal stability, transparency, surface smoothness, ease of handling, and water resistance.

The hole injection electrode 110 may be formed by depositing or sputtering a material having a relatively high work function. Example of a material for forming a hole injection electrode include indium tin oxide (ITO), indium zinc oxide (IZO), tin oxide (SnO₂), and zinc oxide (ZnO). If necessary, the hole injection electrode 110 may include a conductive metal such as aluminum (Al), magnesium (Mg), gold (Au). However, other material may also be used to form the hole injection electrode 110.

An insulating layer 120 defining red, green, and blue sub-pixel regions by defining a red light-emitting region, a green light-emitting region, and a blue light-emitting region is formed in an edge portion of the hole injection electrode 110. The insulating layer 100 may be formed of a conventionally available insulating material, for example, silicon oxide, silicon nitride, or insulating polymer, but may also be formed of other materials.

The hole injection layer 131 may be formed by vacuum deposition, spin coating, casting, Langmuir Blodgett (LB) deposition, or the like.

When the hole injection layer 131 is formed by vacuum deposition, the deposition conditions may vary according to a compound that is used to form the hole injection layer 131, and the structure and thermal properties of the hole injection layer 131 to be formed. For example, the vacuum depositions may be performed at a temperature of about 100 to about 500° C., a pressure of about 10⁻⁸ to about 10⁻³ torr, and a deposition rate of about 0.01 to about 100 Å/sec.

When the hole injection layer 131 is formed by spin coating, the coating conditions may vary according to a compound that is used to form the hole injection layer 131, and the structure and thermal properties of the hole injection layer 131 to be formed. For example, the coating rate may be in the range of about 2000 rpm to about 5000 rpm, and a temperature at which heat treatment is performed to remove a solvent after coating may be in the range of about 80 to about 200° C.

The hole injection layer 131 may be formed of any known materials used to form a hole injection layer. Examples of a material for forming the hole injection layer 131 include, but are not limited to, diphenylbiphenyl-4,4′-diamine (DNTPD), 4,4′,4″-tris (3-methylphenylphenylamino) triphenylamine (m-MTDATA), TDATA, 2T-NATA, polyaniline/dodecylbenzenesulfonic acid (Pani/DBSA), poly(3,4-ethylenedioxythiophene)/poly(4-styrenesulfonate (PEDOT/PSS), polyaniline/camphor sulfonic acid (Pani/CSA), and (polyaniline)/poly(4-styrenesulfonate) (PANI/PSS).

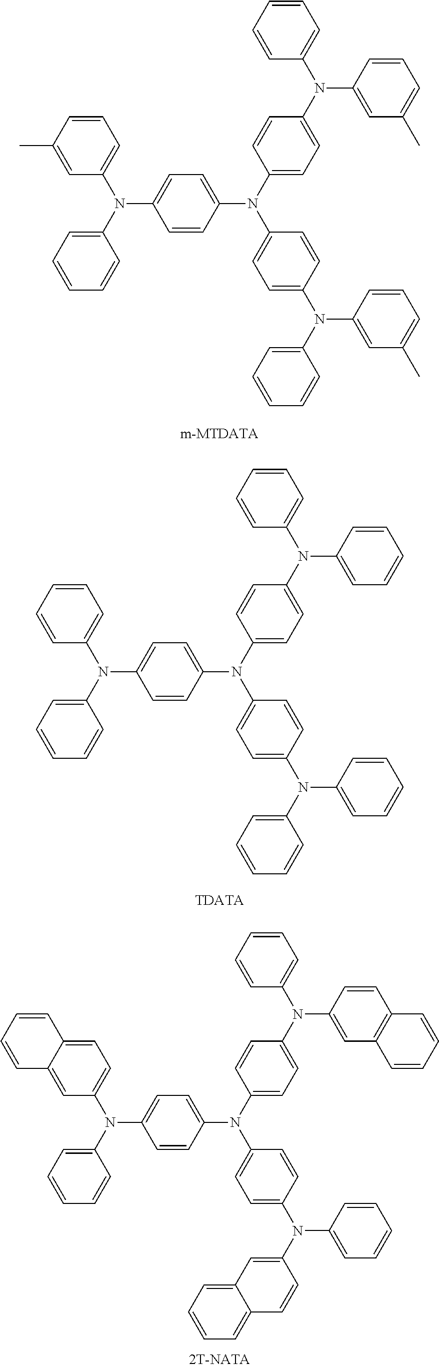

The thickness of the hole injection layer 131 may be in a range of about 100 Å to 10,000 Å, for example, about 100 Å to about 1,000 Å. When the thickness of the hole injection layer 131 is within this range, the hole injection layer 131 may have excellent hole injecting ability without a substantial increase in driving voltage.

The hole transport layer 133 may be formed on the hole injection layer 131 by vacuum deposition, spin coating, casting, Langmuir Blodgett (LB) deposition, or the like. When the hole transport layer 133 is formed by vacuum deposition or spin coating, deposition conditions and coating conditions may vary according to a material that is used to form the hole transport layer 133. In this regard, deposition conditions and coating conditions may be the same or similar to those described with reference to the hole injection layer 131.

The hole transport layer 133 may be formed of any known materials used to form a hole transport layer. Examples of hole transport materials include a carbazole derivative such as N-phenylcarbazole or polyvinylcarbazole, N,N′-di(naphthalene-1-yl)-N,N′-diphenyl benzidine (α-NPD), and 4,4′,4″-tris(N-carbazolyl)triphenylamine (TCTA).

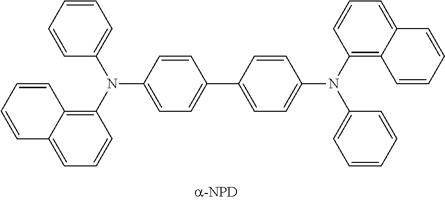

The thickness of the hole transport layer 133 may be in the range of about 50 Å to about 1,000 Å, for example, about 100 Å to about 800 Å. When the thickness of the hole transport layer 133 is within this range, the hole transport layer may have excellent hole transporting ability without a substantial increase in driving voltage.

The emission layer 135 includes a red emission layer 135R patterned in a red light-emitting region and a green emission layer 135G patterned in a green light-emitting region, and a blue emission layer 135B formed as a common layer.

Referring to FIG. 1, the red emission layer 135R and the green emission layer 135G may be interposed between the hole injection electrode 110 and the blue emission layer 135B, in particular, between the hole transport layer 133 and the blue emission layer 135B.

That is, referring to FIG. 1, the blue emission layer 135B formed as a common layer is disposed on the red emission layer 135R patterned in the red light-emitting region and the green emission layer 135G patterned in the green light-emitting region.

Accordingly, in the organic light-emitting device 100, the substrate 101, the hole injection electrode 110, the hole injection layer 131, the hole transport layer 133, the red emission layer 135R, the blue emission layer 135B, the electron transport layer 137, the electron injection layer 139, and the electron injection electrode 140 are sequentially stacked in this stated order in the red light-emitting region; the substrate 101, the hole injection electrode 110, the hole injection layer 131, the hole transport layer 133, the green emission layer 135G, the blue emission layer 135B, the electron transport layer 137, the electron injection layer 139, and the electron injection electrode 140 are sequentially stacked in this stated order in the green light-emitting region; and the substrate 101, the hole injection electrode 110, the hole injection layer 131, the hole transport layer 133, the blue emission layer 135B, the electron transport layer 137, the electron injection layer 139, and the electron injection electrode 140 are sequentially stacked in this stated order in the blue light-emitting region.

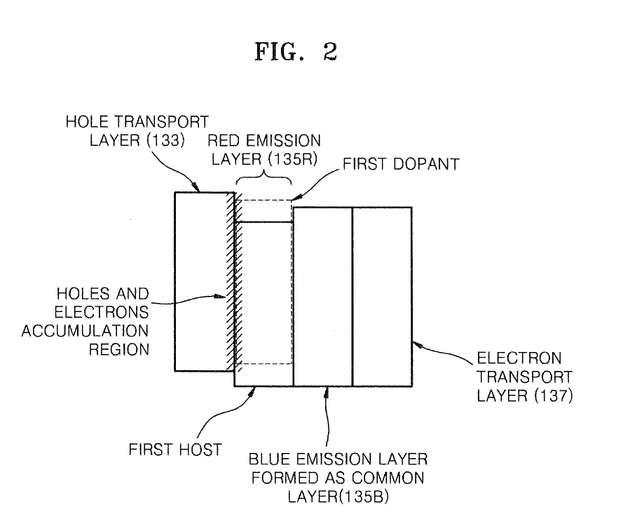

The red emission layer 135R includes a first host and a first dopant, a HOMO level of the first host is lower than a HOMO level of the first dopant, and a LUMO of the first host is lower than a LUMO of the first dopant. As a result, an energy diagram relation illustrated in FIG. 2 is formed and thus, in the red light-emitting region, holes which are injected from the hole injection electrode 110 and pass through the hole injection layer 131 and the hole transport layer 133 accumulate at the interface between the red emission layer 135R and the hole transport layer 133, and electrons which are injected from the electron injection electrode 140 and pass through the electron injection layer 139 and the electron transport layer 137 pass through the blue emission layer 135B and accumulate at the interface between the red emission layer 135R and the hole transport layer 133. Thus, a red emission may occur mostly at the interface between the red emission layer 135R and the hole transport layer 133.

That is, when the HOMO and LUMO levels of the first host and dopants contained in the red emission layer 135R are adjusted, excitons formed by combining holes and electrons are generated mostly at the interface between the red emission layer 135R and the hole transport layer 133. Thus, in the red light-emitting region, red emission occurs, and blue emission by the blue emission layer 135B as a common layer may not occur or may be minimal, if any.

A difference between the HOMO level of the first host and the HOMO level of the first dopant may be 0.1 eV or more, for example, in the range of 0.2 eV to 1.0 eV. In addition, a difference between the LUMO level of the first host and the LUMO level of the first dopant may be 0.1 eV or more, for example, in the range of 0.2 eV to 1.0 eV. When the differences of the HOMO and LUMO levels between the first host and the first dopant are within the ranges (i.e., 0.1 eV or more) described above, excitons are generated mostly at the interface between the red emission layer 135R and the hole transport layer 133 and a blue emission may not substantially occur in the blue emission layer 135B as a common layer in the red light-emitting region.

In consideration of the characteristic described above, the first host (that is, a host included in the red emission layer 135R) may be selected from materials having a HOMO level of −6.5 eV to −5.0 eV and a LUMO level of −3.5 eV to −2.0 eV, and the first dopant (that is, a dopant included in the red emission layer 135R) may be selected from materials having a HOMO level of −6.0 eV to −4.0 eV, and a LUMO level of −3.0 eV to −1.0 eV. However, the first host and the first dopant may also be formed using other materials.

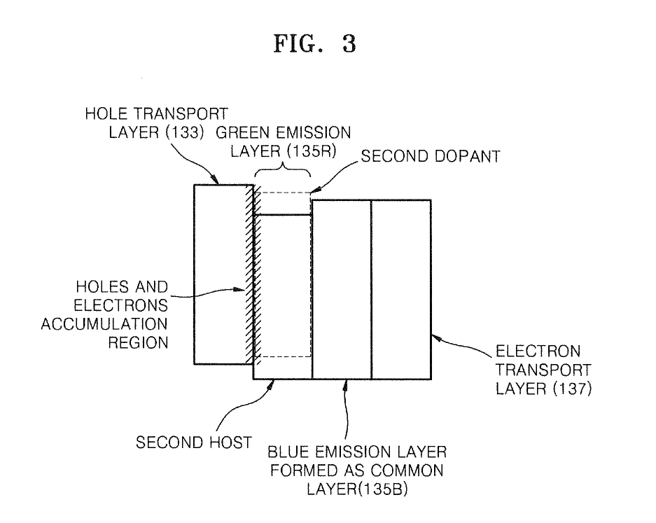

The green emission layer 135G includes a second host and a second dopant, and a HOMO level of the second host is lower than a HOMO level of the second dopant, and a LUMO of the second host is lower than a LUMO of the second dopant. As a result, an energy diagram relation similar to the view illustrated in FIG. 2 is formed. (See FIG. 3.) Thus, in the green light-emitting region, holes which are injected from the hole injection electrode 110 and pass through the hole injection layer 131 and the hole transport layer 133 accumulate at the interface between the green emission layer 135G and the hole transport layer 133, and electrons which are injected from the electron injection electrode 140 and pass through the electron injection layer 139, the electron transport layer 137 and the blue emission layer 135B accumulate at the interface between the green emission layer 135G and the hole transport layer 133. Thus, a green emission may occur mostly at the interface between the green emission layer 135G and the hole transport layer 133.

That is, when the HOMO and LUMO levels of the second host and dopants contained in the green emission layer 135G are adjusted, excitons formed by combining holes and electrons are generated at the interface between the green emission layer 135G and the hole transport layer 133. Thus, in the green light-emitting region, green emission occurs, and blue emission by the blue emission layer 1358 as a common layer may not occur in the green light-emitting region or may be minimal, if any.

A difference between the HOMO level of the second host and the HOMO level of the second dopant may be 0.1 eV or more, for example, in the range of 0.2 eV to 1.0 eV. In addition, a difference between the LUMO level of the second host and the LUMO level of the second dopant may be 0.1 eV or more, for example, in the range of 0.2 eV to 1.0 eV. When the differences of the HOMO and the LUMO levels between the second host and the second dopant are within the ranges (i.e., 0.1 eV or more) described above, excitons are generated mostly at the interface between the green emission layer 135G and the hole transport layer 133, and a blue emission may not occur in the blue emission layer 135B as a common layer or may be minimal, if any.

In consideration of the characteristic described above, the second host (that is, a host included in the green emission layer 135G) may be selected from materials having a HOMO level of −6.5 eV to −5.0 eV, and a LUMO level of −3.5 eV to −2.0 eV, and the second dopant (that is, a dopant included in the green emission layer 135G) may be selected from materials having a HOMO level of −6.0 eV to −4.0 eV and a LUMO level of −3.0 eV to −1.0 eV. However, the second host and the second dopant may also be formed using other materials.

The first host and the first dopant may be selected from hosts and dopants that satisfy the HOMO and LUMO level ranges described above and contribute red emission. In addition, the second host and the second dopant may be selected from hosts and dopants that satisfy the HOMO and LUMO level ranges described above and contribute green emission.

For example, the first host and the second host may be, each independently, selected from the group consisting of a carbazole-based compound, an organic metal complex, an oxadiazole-based compound, a phenanthroline-based compound, a triazine-based compound, a triazole-based compound, a spirofluorene-based compound, TPBi, and a combination thereof:

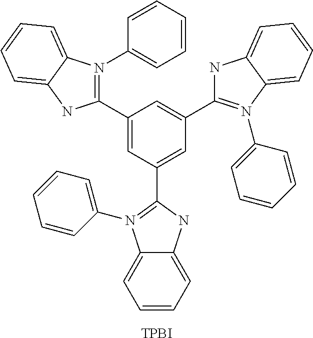

For example, the carbazole-based compound may be selected from the group consisting of 1,3,5-tricarbazolylbenzene, 4,4′-biscarbazolylbiphenyl(CBP), m-biscarbazolylphenyl, 4,4′-biscarbazolyl-2,2′-dimethylbiphenyl, 4,4′,4″-tri(N-carbazolyl) triphenylamine, 1,3,5-tri(2-carbazolyl phenyl)benzene, 1,3,5-tris(2-carbazolyl-5-methoxyphenyl)benzene, and bis(4-carbazolyl phenyl)silane, but is not limited thereto.

For example, the organic metal complex may be selected from the group consisting of bis(8-hydroxyquinolato)biphenoxy metal, bis(8-hydroxyquinolato)phenoxy metal, bis(2-methyl-8-hydroxyquinolato)biphenoxy metal, bis(2-methyl-8-hydroxyquinolato)phenoxy metal, bis(2-methyl-8-quinolinolato)(para-phenyl-phenolato)metal, bis(2-(2-hydroxyphenyl)quinolato)metal, bis(2-methyl-8-quinolinolato-N1, 08)-(1,1′-biphenyl-4-olato)metal, and a combination thereof. In this regard, the metal may be aluminum (AI), zinc (Zn), beryllium (Be) or gallium (Ga), but is not limited thereto. For example, the organic metal complex is bis(2-methyl-8-quinolinolato-N1, 08)-(1,1′-biphenyl-4-olato) aluminum (Balq), but is not limited thereto.

For example, the organic metal complex may be bis(8-hydroxyquinolato)biphenoxy aluminum, bis(8-hydroxyquinolato)phenoxy aluminum, bis(2-methyl-8-hydroxyquinolato)biphenoxy aluminum, bis(2-methyl-8-hydroxyquinolato)phenoxy aluminum, bis(2-(2-hydroxyphenyl)quinolato)zinc, or bis(2-methyl-8-quinolinolato)(para-phenyl-phenolato)aluminum.

The oxadiazole-based compound may be (4-biphenylyl)-5-(4-tertbutylphenyl)-1,3,4-oxadiazolyl, but is not limited thereto.

The phenanthroline-based compound may be 2,9-dimethyl-4,7-diphenyl-9,10-phenanthroline, but is not limited thereto.

The triazine-based compound may be selected from the group consisting of 2,4,6-tris(diarylamino)-1,3,5-triazine, 2,4,6-tris(diphenylamino)-1,3,5-tirazine, 2,4,6-tricarbazolo-1,3,5-triazine, 2,4,6-tris(N-phenyl-2-naphthylamino)-1,3,5-triazine, 2,4,6-tris(N-phenyl-1-naphthylamino)1,3,5-triazine, and 2,4,6-trisbiphenyl-1,3,5-triazine, but is not limited thereto.

The triazole-based compound may be 3-phenyl-4-(1′-naphthyl)-5-phenyl-1,2,4-triazol, but is not limited thereto.

The spirofluorene-based compound may be selected from the group consisting of phenylspirofluorene, biphenylspirofluorene and methylspirofluorene, but is not limited thereto.

The first dopant and the second dopant may be selected from the group consisting of bisthienylpyridine acetylacetonate iridium, bis(benzothienylpyridine)acetylacetonate iridium, bis(2-phenylbenzothiazole)acetylacetonate iridium, bis(1-phenylisoquinoline)iridium acetylacetonate, tris(1-phenylisoquinoline)iridium, tris(2-phenylpyridine)iridium(Ir(ppy)₃) and a combination thereof, but is not limited thereto.

The blue emission layer 135B is formed as a common layer. That is, the blue emission layer 135B is not formed in the blue-emitting region only, but, is also formed in the red light-emitting region, the green light-emitting region, and the blue light-emitting region. However, by adjusting the HOMO level of the first host of the red emission layer 135R to be lower than the HOMO level of the first dopant of the red emission layer 135R, and the LUMO level of the first host of the red emission layer 135R to be lower than the LUMO level of the first dopant of the red emission layer 135R, although the blue emission layer 135B is formed as a common layer, a blue emission by the blue emission layer 135B may not occur in the red light-emitting region. Even in the green light-emitting region, a blue emission may not occur.

Meanwhile, in the blue light-emitting region, a blue emission by the blue emission layer 135B occurs. Thus, when the organic light-emitting device 100 illustrated in FIG. 1 is used, a full-color organic light-emitting display apparatus having excellent color purity in terms of red, green, and blue may be embodied.

The blue emission layer 135B may include a known blue light-emitting material, and may include a single material, or a host and a dopant.

Examples of a host for the blue emission layer 135B include aluminum tris(8-hydroxyquinoline) (Alq₃), 4,4′-N,N′-dicarbazole-biphenyl (CBP), 9,10-dinaphthylanthracene (ADN), 4,4′,4″-tris(N-carbazolyl)-triphenylamine) (TCTA), Compound 1 below, Compound 2 below, Compound 3 below, Compound 4 below, dmCBP, Liq, 1,3,5-tris(N-phenylbenzimidazole-2-yl)benzene) (TPBI), Balq, and BCP, but are not limited thereto.

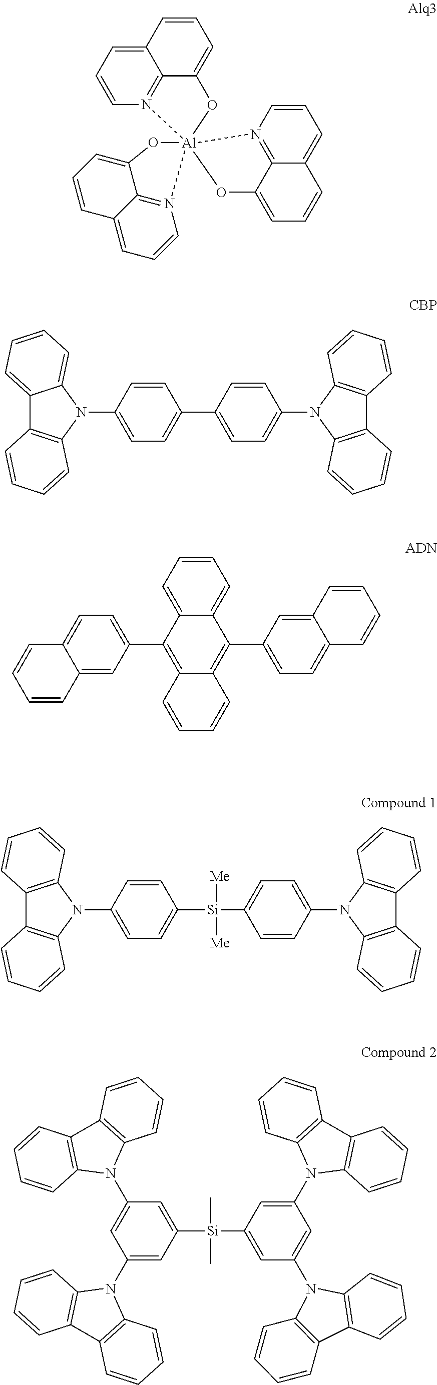

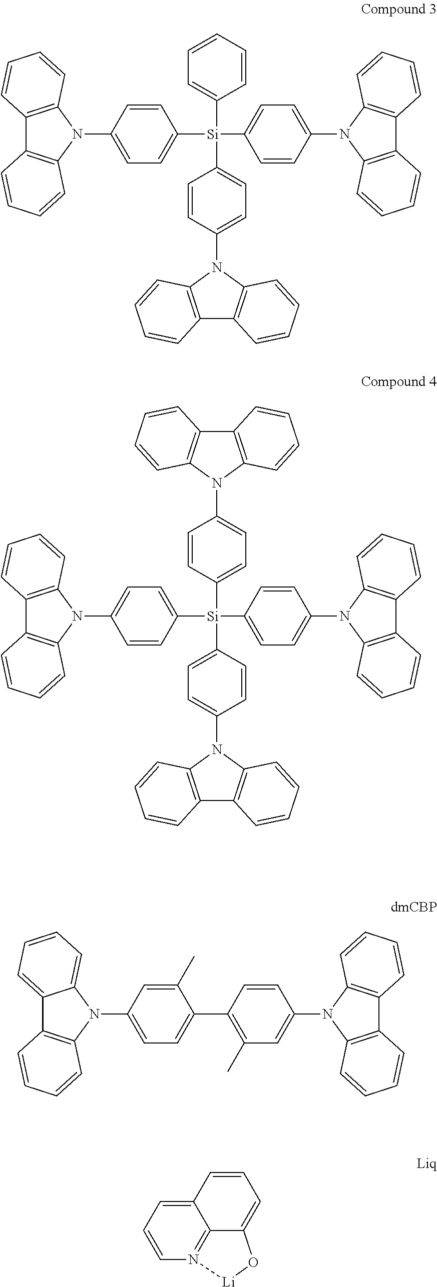

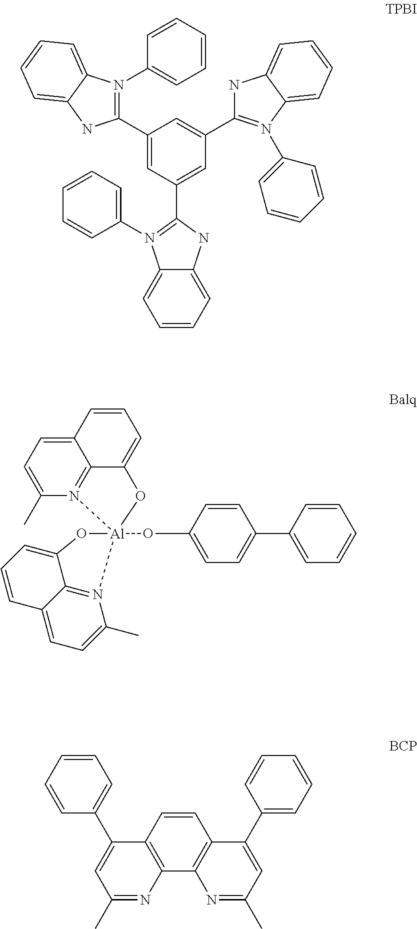

Examples of known blue dopants for the blue EML 135B include F₂Irpic, (F₂ppy)₂Ir(tmd), Ir(dfppz)₃, ter-fluorene, 4,4′-bis(4-diphenylaminostyryl)biphenyl (DPAVBi), and 2,5,8,11-tetra-tert-butylperylene (TBP), but are not limited thereto.

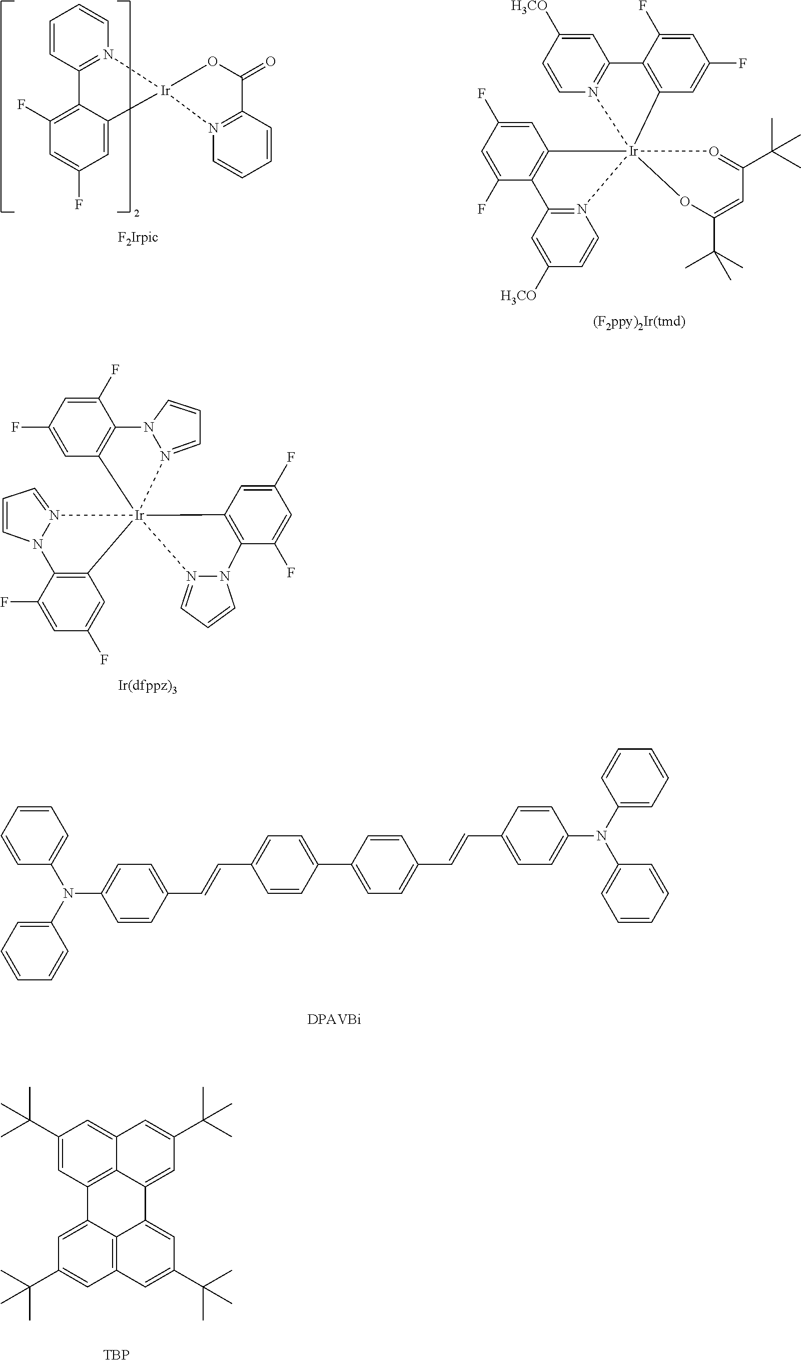

The blue emission layer 135B may also include one or more of compounds represented by Formulae 1 to 3:

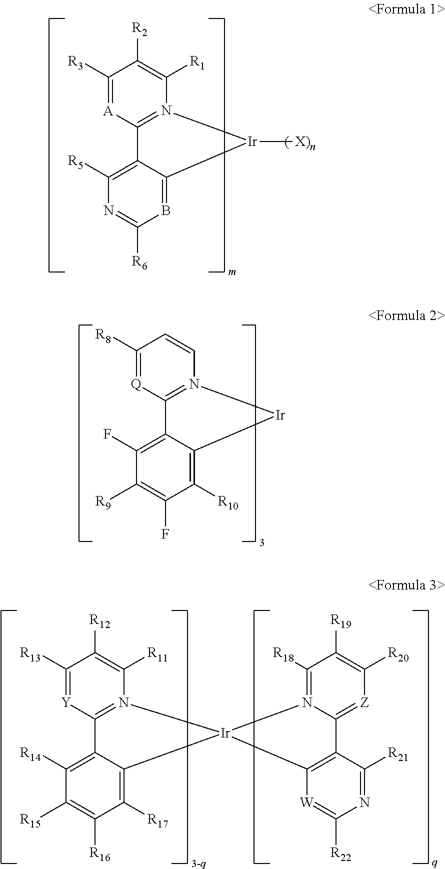

where

A is —C(R₄)— or —N—;

B is —C(R₇)— or —N—;

R₁ to R₇ may be each independently selected from the group consisting of a hydrogen atom, a cyano group, a hydroxy group, a nitro group, a halogen atom, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₇-C₂₀ arylalkyl group, a substituted or unsubstituted C₂-C₂₀ alkylalkoxy group, a substituted or unsubstituted C₇-C₂₀ arylalkoxy group, a substituted or unsubstituted C₆-C₂₀ arylamino group, a substituted or unsubstituted C₁-C₂₀ alkylamino group, a substituted or unsubstituted C₆-C₂₀ arylamino group, and a substituted or unsubstituted C₂-C₂₀ heterocyclic group, wherein at least two substituents selected from among R₁ through R₄, R₄ and R₅, and R₄ and R₆ may be respectively linked to form saturated or unsaturated carbon rings or saturated or unsaturated hetero rings;

X is a monovalent anionic bidentate ligand;

m is 2 or 3;

n is 0 or 1;

the sum of m and n is 3;

Q is CH or N;

R₈ to R₁₀ may be each independently selected from the group consisting of a hydrogen atom, a cyano group, a hydroxy group, a thiol group, a nitro group, a halogen atom, a substituted or unsubstituted C₁-C₃₀ alkyl group, a substituted or unsubstituted C₁-C₃₀ alkoxy group, a substituted or unsubstituted C₂-C₃₀ alkenyl group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₃₀ cycloalkyl group, a substituted or unsubstituted C₂-C₃₀ heterocycloalkyl group, a substituted or unsubstituted C₁-C₃₀ alkylcarbonyl group, a substituted or unsubstituted C₇-C₃₀ arylcarbonyl group, a C₁-C₃₀ alkylthio group, —Si(R′)(R″)(R′″) wherein R′ and R″ are each independently a hydrogen atom or a C₁-C₃₀ alkyl group, and —N(R′)(R″) wherein R′ and R″ are each independently a hydrogen atom or a C₁-C₃₀ alkyl group;

Y, Z and W each are —CH— or —N—;

R₁₁ to R₂₂ may be each independently selected from the group consisting of a hydrogen atom, a cyano group, a hydroxyl group, a nitro group, a halogen atom, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₇-C₂₀ arylalkyl group, a substituted or unsubstituted C₂-C₂₀ alkylalkoxy group, a substituted or unsubstituted C₇-C₂₀ arylalkoxy group, a substituted or unsubstituted C₆-C₂₀ arylamino group, a substituted or unsubstituted C₁-C₂₀ alkylamino group, a substituted or unsubstituted C₆-C₂₀ arylamino group, and a substituted or unsubstituted C₂-C₂₀ heterocyclic group, wherein at least two substituents selected from among R₁₁ through R₁₃, at least two substituents selected from among R₁₈ through R₂₀, R₁₄ and R₁₅, R₁₅ and R₁₆, and R₁₆ and R₁₇ may be respectively linked to form saturated or unsaturated carbon rings, or saturated or unsaturated hetero rings; and

q is 1 or 2.

In regards to Formula 1, the blue emission layer 135B may include a compound represented by Formula 1a:

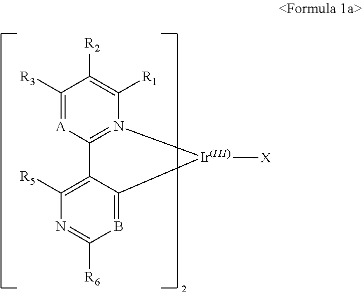

wherein A may be —C(R₄)— or —N—; R₁, R₂, and R₄ all may be hydrogen atoms; R₃ may be an electron donating group selected from a hydrogen atom, a methyl group, a methoxy group, an isopropyl group, a phenyloxy group, a benzyloxy group, a dimethylamino group, a diphenylamino group, a pyrrolidine group, and a phenyl group; B may be —C(R₇)— or —N—; R₅, R₆, and R₇ may be each independently an electron withdrawing group selected from the group consisting of a hydrogen atom, a fluorine, a cyano group, a nitro group, a benzene substituted with a fluorine or a trifluoromethyl group, or trifluoromethyl group; and X may be selected from the group consisting of acetylacetonate (acac), hexafluoroacetylacetonate (hfacac), picolinate (pic), salicylanilide (sal), quinolinecarboxylate (quin), 8-hydroxyquinolinate (hquin), L-proline (L-pro), 1,5-dimethyl-3-pyrazolecarboxylate (dm3 pc), imineacetylacetonate (imineacac), dibenzoylmethane (dbm), tetramethyl heptanedionate (tmd), 1-(2-hydroxyphenyl)pyrazolate (oppz), and phenylpyrazole (ppz).

Alternatively, the blue emission layer 135B may include a compound represented by Formula 1b below:

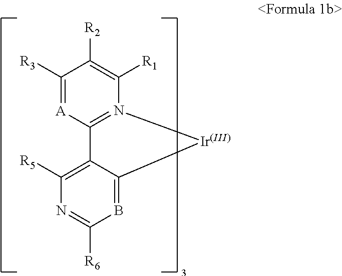

wherein A may be —C(R₄)— or —N—; R₁, R₂, and R₄ all may be hydrogen atoms; R₃ may be an electron donating group selected from a hydrogen atom, a methyl group, a methoxy group, an isopropyl group, a phenyloxy group, a benzyloxy group, a dimethylamino group, a diphenylamino group, a pyrrolidine group, and a phenyl group; B may be —C(R₇)— or —N—; and R₅, R₆, and R₇ may be each independently an electron withdrawing group selected from the group consisting of a hydrogen atom, a fluorine, a cyano group, a nitro group, a benzene substituted with a fluorine or a trifluoromethyl group, or trifluoromethyl group.

In the Formulae 1 and 1a, X may refer to the following structures:

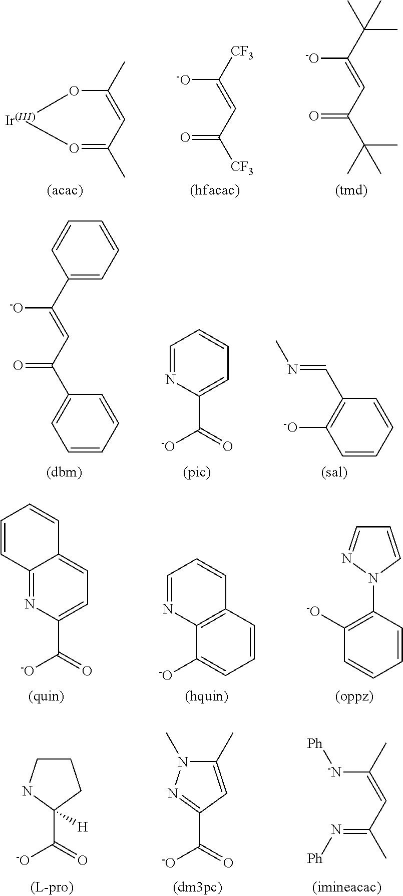

For example, the compound represented by Formula 1 may be the compound represented by Formula 1c, but is not limited thereto:

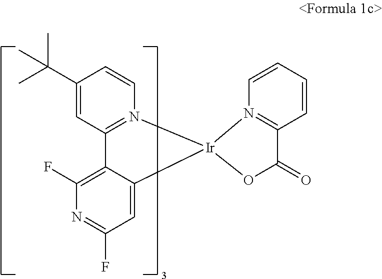

### BD 782

In regards to Formula 2, when Q is CH in Formula 2, R₈ may be an electron donating group, and R₉ may be an electron withdrawing group. Examples of the electron donating group include, but are not limited thereto, a methyl group, an isopropyl group, a phenyloxy group, a benzyloxy group, a dimethylamino group, a diphenylamino group, a pyrrolidine group, and a phenyl group, and examples of the electron withdrawing group include, but are not limited thereto, a fluorine, a cyano group, a trifluoromethyl group, and a phenyl group containing a trifluoromethyl group.

For example, in Formula 2, Q may be CH or N, R₈ may be a hydrogen atom, a methyl group, a pyrrolidine group, a dimethylamino group, or a phenyl group, R₉ may be a cyano group, CF₃, C₆F₅, or a nitro group, and R₁₀ is a hydrogen atom or a cyano group.

For example, exemplary examples of Formula 2 may include Formulae 2a to 2c, but are not limited thereto.

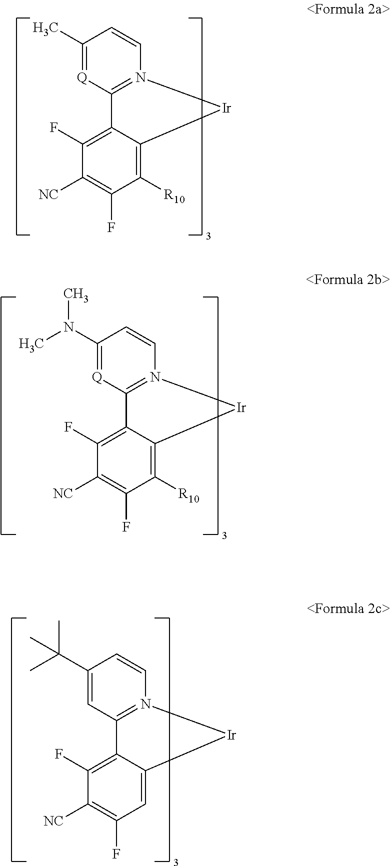

### BD 735F

In regards to Formula 3, Y may be —CH— or —N—; R₁₁ and R₁₂ each may be a hydrogen atom; R₁₃ may be an electron donating group selected from the group consisting of a hydrogen atom, a methyl group, a methoxy group, an isopropyl group, a tert-butyl group, a phenyloxy group, a benzyloxy group, a dimethylamino group, a diphenylamino group, a pyrrolidine group, and a phenyl group; Z may be —CH— or —N—; R₁₈ and R₁₉ each may be a hydrogen atom; R₂₀ may be an electron donating group selected from the group consisting of a hydrogen atom, a methyl group, a methoxy group, an isopropyl group, a tert-butyl group, a phenyloxy group, a benzyloxy group, a dimethylamino group, a diphenylamino group, a pyrrolidine group, and a phenyl group; and R₁₄, R₁₅, R₁₆, R₁₇, R₂₁, and R₂₂ may be each independently an electron withdrawing group selected from the group consisting of a hydrogen atom, a fluorine, a cyano group, a nitro group, a phenyl group substituted with a fluorine or a trifluoromethyl group, and a trifluoromethyl group.

For example, exemplary examples of Formula 3 include Formulae 3a and 3b, but are not limited thereto:

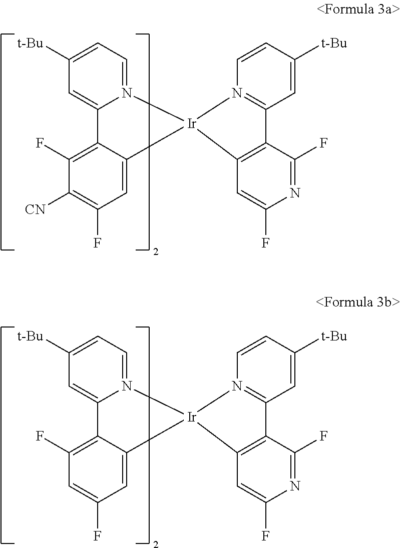

The unsubstituted C₁-C₃₀ alkyl group used herein may be methyl, ethyl, propyl, isobutyl, sec-butyl, pentyl, iso-amyl, hexyl, or the like. At least one hydrogen atom in the alkyl group may be substituted with a halogen atom, a hydroxyl group, a nitro group, a cyano group, an amino group, an amidino group, hydrazine, hydrazone, a carboxyl group or salt thereof, a sulfuric acid or salt thereof, a phosphoric acid or salt thereof, a C₁-C₃₀ alkyl group, a C₂-C₃₀ alkenyl group, a C₂-C₃₀ alkynyl group, a C₆-C₃₀ aryl group, a C₇-C₃₀ arylalkyl group, a C₂-C₂₀ heteroaryl group, or a C₃-C₃₀ heteroarylalkyl group.

Examples of the unsubstituted C₁-C₃₀ alkoxy group used herein include a methoxy group, an ethoxy group, and an isopropyl group, wherein at least one hydrogen atom of the alkoxy group may be substituted with the same substituent as described above in connection with the alkyl group.

The unsubstituted aryl group used herein may be used alone or in combination, and refers to an aromatic C₆-C₃₀ carbocyclic system containing at least one ring. The rings may be bound to each other using a pendant method or may be fused to each other. Examples of the aryl group include phenyl, naphthyl, tetrahydronaphthyl, and the like. At least one hydrogen atom of the aryl group may be substituted with the same substituent as described above in connection with the alkyl group.

Examples of the unsubstituted aryloxy group used herein include phenyloxy, naphthyleneoxy, and diphenyloxy. At least one hydrogen atom of the aryloxy group may be substituted with the same substituent as described above in connection with the alkyl group.

The unsubstituted arylalkyl group used herein refers to an aryl group as defined above, whose hydrogen atoms are partially substituted by a lower alkyl group, such as a methyl, ethyl, or propyl group. For example, the arylalkyl group may be benzyl, phenylethyl, etc. At least one hydrogen atom of the arylalkyl group may be substituted with the same substituent as described above in connection with the alkyl group.

The unsubstituted heteroaryl group used herein is a monovalent monocyclic or divalent bicyclic aromatic organic compound that includes 6-70 ring atoms, wherein 1, 2 or 3 ring atoms are hetero atoms selected from N, O, P or S and the other ring atoms are carbon atoms. Examples of the heteroaryl group include thienyl, pyridyl, and furyl. At least one hydrogen atom of the heteroaryl group may be substituted with the same substituent as described above in connection with the alkyl group.

The unsubstituted heteroaryloxy group used herein refers to a heteroaryl group as defined above to which oxygen is bound. For example, the unsubstituted heteroaryloxy group may be benzyloxy or phenylethyloxy. At least one hydrogen atom of the heteroaryloxy group may be substituted with the same substituent as described above in connection with the alkyl group.

The unsubstituted arylalkyloxy group used herein may be a benzyloxy group. At least one least one hydrogen atom of the arylalkyloxy group may be substituted with the same substituent as described above in connection with the alkyl group.

The unsubstituted heteroarylalkyl group used herein refers to a heteroaryl group as defined above having hydrogen atoms that are partially substituted by an alkyl group. At least one hydrogen atom of the heteroarylalkyl group may be substituted with the same substituent as described above in connection with the alkyl group.

The unsubstituted cycloalkyl group used herein may be a cyclohexyl group, a cyclopentyl group, or the like. At least one hydrogen atom of the cycloalkyl group may be substituted with the same substituent as described above in connection with the alkyl group.

The unsubstituted C₁-C₃₀ alkylcarbonyl group used herein may be an acetyl group, an ethyl carbonyl group, an isopropyl carbonyl group, a phenyl carbonyl group, a naphthalene carbonyl group, a diphenyl carbonyl group, a cyclohexyl carbonyl group, or the like. At least one hydrogen atom of the alkylcarbonyl group may be substituted with the same substituent as described above in connection with the alkyl group.

Examples of the unsubstituted C₇-C₃₀ arylcarbonyl group used herein include a phenyl carbonyl group, a naphthalene carbonyl group, a diphenyl carbonyl group, and the like. At least one hydrogen atom of the arylcarbonyl group may be substituted with the same substituent as described above in connection with the alkyl group.

In the red emission layer 135R, the green emission layer 135G, and the blue emission layer 135B, a doping concentration of a dopant may not be limited. For example, the content of the dopant may be in a range of 0.01 to 20 parts by weight based on 100 parts by weight of a host.

The red emission layer 135R, the green emission layer 135G, and the blue emission layer 135B may be formed by vacuum deposition, spin coating, casting, LB deposition, or the like. When the red emission layer 135R, the green emission layer 135G, and the blue emission layer 135B are formed by vacuum deposition or spin coating, the conditions for deposition and coating may be similar to those for the formation of the hole injection layer 131, although the conditions for deposition and coating may vary according to the material that is used to form the emission layer 135.

The thickness of each of the red emission layer 135R, the green emission layer 135G, and the blue emission layer 135B may be in the range of about 100 Å to 1000 Å, for example, 200 Å to 600 Å. When the thickness of the emission layer is within this range, the emission layer may have excellent light emitting ability without a substantial increase in driving voltage.

The electron transport layer 137 may be formed by vacuum deposition, spin coating, or casting. When the electron transport layer 137 is formed by vacuum deposition or spin coating, the conditions for deposition and coating may be similar to those for the formation of the hole injection layer 131, although the conditions for deposition and coating may vary according to the material that is used to form the electron transport layer 137. The electron transport layer 137 may be formed of a material that can stably transport electrons injected from the electron injection electrode 140. For example, the material used to form the electron transport layer 137 may be any known quinoline derivative, such as tris(8-quinolinorate)aluminum (Alq3), TAZ, or Balq, but is not limited thereto.

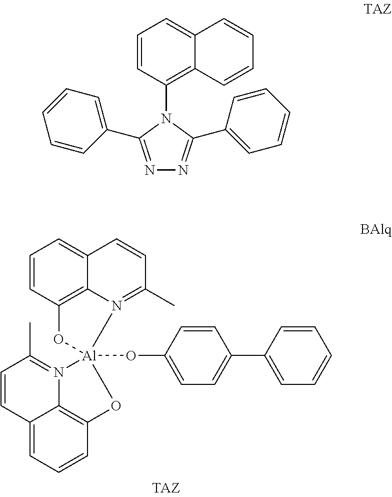

The thickness of the electron transport layer 137 may be in the range of about 100 to about 1,000 Å, for example, about 150 to about 500 Å. When the thickness of the electron transport layer 137 is within this range, the electron transport layer 137 may have satisfactory electron transporting ability without a substantial increase in driving voltage.

The electron injection layer 139 may include a material that facilitates injection of electrons from the electron injection electrode 140.

The electron injection layer 139 may be formed of any known electron injection material such as LiF, NaCl, CsF, Li₂O, or BaO. Deposition conditions for forming the electron injection layer 139 may vary according to a material that is used to form the electron injection layer 139, but may be similar to those described in connection with the hole injection layer 131.

The thickness of the electron injection layer 139 may be in the range of about 1 to about 100 Å, for example, about 5 to about 50 Å. When the thickness of the electron injection layer 139 is within this range, the electron injection layer 139 may have satisfactory electron injection ability without a substantial increase in driving voltage.

The electron injection electrode 140 may be formed of a metal, an alloy, an electrically conductive compound, materials, or a combination of thereof which have a relatively low work function. Examples of such materials may include, but are not limited to, lithium (Li), magnesium (Mg), aluminum (Al), aluminum-lithium (Al—Li), calcium (Ca), magnesium-indium (Mg—In), and magnesium-silver (Mg—Ag). In addition, a transparent cathode formed of ITO or IZO may be used to manufacture a top-emission light emitting device.

An organic light-emitting device according to an embodiment of the present invention has been described by referring to the organic light-emitting device 100 illustrated in FIG. 1 as an example. However, if necessary, only one layer of either the red emission layer 135R or the green emission layer 135G may be formed, or a hole blocking layer may be further interposed between the emission layer 135 and the electron transport layer 137.

The present invention will be described in further detail with reference to the following examples. These examples are for illustrative purposes only and are not intended to limit the scope of the present invention.

### EXAMPLE

### Example 1

To manufacture an anode, a corning 15 Ω/cm² (1200 Å) ITO glass substrate was cut to a size of 50 mm×50 mm×0.7 mm and then sonicated in isopropyl alcohol and pure water each for five minutes, and then cleaned by irradiation of ultraviolet (UV) rays for 30 minutes and exposure to ozone. The resulting glass substrate was mounted on a vacuum deposition device. diphenylbiphenyl-4,4′-diamine (DNTPD) as a hole injection layer was vacuum deposited on the ITO, thereby forming a hole injection layer having a thickness of 200 Å. NPB as a hole transport material was vacuum deposited on the hole injection layer, thereby forming a hole transport layer having a thickness of 500 Å. Balq as a host and Ir(ppy)₃ as a dopant (the doping concentration of the dopant: 15 wt %) were deposited on the hole transport layer, thereby forming a green emission layer having a thickness of 300 Å (herein, Balq as a host has a HOMO level of about −5.9 eV and a LUMO level of about −3.0 eV, and Ir(ppy)₃ as a dopant has a HOMO level of about −5.5 eV and a LUMO level of about −2.8 eV), and then 9,10-dinaphthylanthracene (ADN) as a host and DPBVi as a dopant were vacuum deposited as a blue light-emitting material on the green emission layer (the doping concentration of the dopant: 5 wt %), thereby forming a blue emission layer having a thickness of, 200 Å. Then, Alq₃ was deposited on the blue emission layer to form an electron transport layer having a thickness of 200 Å, and then LiF was deposited on the electron transport layer to form an electron injection layer having a thickness of 10 Å. Then, Al was deposited on the electron injection layer to a thickness of 1000 Å (electron injection electrode), thereby completing the manufacture of an organic light-emitting device.

The organic light-emitting device showed a current density of 14 mA/cm² and a luminescence of 1000 cd/m² at a direct current voltage of 7 V, and a CIE color coordinate of x=0.32 and y=0.60. That is, the organic light-emitting device showed a green emission having excellent color purity.

### Example 2

An organic light-emitting device was manufactured in the same method as in Example 1, except that TPBi (TPBi has a HOMO level of −6.3 eV and a LUMO level of −2.9 eV) was used as a host of the green emission layer.

The organic light-emitting device showed a current density of 20 mA/cm² and a luminescence of 1800 cd/m² at a direct current voltage of 7 V, and a CIE color coordinate of x=0.29 and y=0.61. That is, the organic light-emitting device showed a green emission having excellent color purity.

### Comparative Example 1

An organic light-emitting device was manufactured in the same method as in Example 1, except that CBP was used as a host of the green emission layer. In this regard, CBP as a host has a HOMO level of about −5.8 eV and a LUMO level of about −2.5 eV (the LUMO level (−2.5 eV) of CBP as a host is higher than the LUMO level (−2.8 eV) of Ir(ppy)₃ as a dopant.

The organic light-emitting device showed a current density of 15 mA/cm² and a luminescence of 1000 cd/m² at a direct current voltage of 7 V, and an emission wavelength was 440 nm which belongs to a blue light-emitting region. In addition, a CIE color coordinate was x=0.15 and y=0.39. Thus, it can be seen that the green emission of the organic light-emitting device has poorer color purity lower than that of the organic light-emitting device of Example 1.

As described above, according to the one or more of the above embodiments of the present invention, an organic light-emitting device includes one or more emission layer of a red emission layer patterned in a red light-emitting region and a green emission layer patterned in a green light-emitting region and a blue emission layer formed as a common layer, and thus a blue emission in at least one region of the red light-emitting region and the green light-emitting region may be prevented, thereby enabling high-quality emissions.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. An organic light-emitting device, comprising:
a substrate;
a pair of electrodes on the substrate, the pair of electrodes comprising a hole injection electrode and an electron injection electrode; and
an emission layer interposed between the pair of electrodes, the emission layer comprising at least one of a red emission layer patterned in a red light-emitting region and a green emission layer patterned in a green light-emitting region, and a blue emission layer formed as a common layer covering said at least one of the red emission layer and the green emission layer and a blue light-emitting region, the blue emission layer positioned between the electron injection electrode and said at least one of the red emission layer and the green emission layer;
wherein, when the emission layer comprises the red emission layer, the red emission layer comprises a first host and a first dopant, a highest occupied molecular orbital (HOMO) level of the first host is lower than a highest occupied molecular orbital (HOMO) level of the first dopant, and a lowest occupied molecular orbital (LUMO) level of the first host is lower than a lowest occupied molecular orbital (LUMO) level of the first dopant; and
when the emission layer comprises the green emission layer, the green emission layer comprises a second host and a second dopant, a highest occupied molecular orbital (HOMO) level of the second host is lower than a highest occupied molecular orbital (HOMO) level of the second dopant, and a lowest occupied molecular orbital (LUMO) level of the second host is lower than a lowest occupied molecular orbital (LUMO) level of the second dopant.

2. The organic light-emitting device of claim 1, wherein the emission layer comprises the red emission layer, and a difference between the HOMO level of the first host and the HOMO level of the first dopant is at least 0.1 eV.

3. The organic light-emitting device of claim 1, wherein the emission layer comprises the red emission layer, and a difference between the LUMO level of the first host and the LUMO level of the first dopant is at least 0.1 eV.

4. The organic light-emitting device of claim 1, wherein the emission layer comprises the green emission layer, and a difference between the HOMO level of the second host and the HOMO level of the second dopant is at least 0.1 eV.

5. The organic light-emitting device of claim 1, wherein the emission layer comprises the green emission layer, and a difference between the LUMO level of the second host and the LUMO level of the second dopant is at least 0.1 eV.

6. The organic light-emitting device of claim 1, wherein the first host and the second host are each independently selected from the group consisting of a carbazole-based compound, an organic metal complex, an oxadiazole-based compound, a phenanthroline-based compound, a triazine-based compound, a triazole-based compound, a spirofluorene-based compound, TPBi, and a combination thereof:

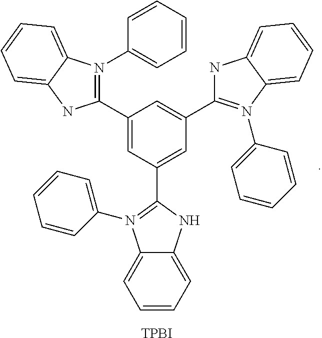

7. The organic light-emitting device of claim 6, wherein the carbazole-based compound is selected from the group consisting of 1,3,5-tricarbazolylbenzene, 4,4′-biscarbazolylbiphenyl(CBP), m-biscarbazolylphenyl, 4,4′-biscarbazolyl-2,2′-dimethylbiphenyl, 4,4′,4″-tri(N-carbazolyl)triphenylamine, 1,3,5-tri(2-carbazolyl phenylbenzene, 1,3,5-tris(2-carbazolyl-5-methoxyphenyl)benzene, and bis(4-carbazolyl phenyl)silane.

8. The organic light-emitting device of claim 6, wherein the organic metal complex is selected from the group consisting of bis(8-hydroxyquinolato)biphenoxy metal, bis(8-hydroxyquinolato)phenoxy metal, bis(2-methyl-8-hydroxyquinolato)biphenoxy metal, bis(2-methyl-8-hydroxyquinolato)phenoxy metal, bis(2-methyl-8-quinolinolato)(para-phenyl-phenolato)metal, bis(2-(2-hydroxyphenyl)quinolato)metal, and a combination thereof, and the metal is aluminum (Al) zinc (Zn), beryllium (Be) or gallium (Ga).

9. The organic light-emitting device of claim 6, wherein the oxadiazole-based compound is (4-biphenylyl)-5-(4-tertbutylphenyl)-1,3,4-oxadiazole, and the phenanthroline-based compound is 2,9-dimethyl-4,7-diphenyl-9,10-phenanthroline.

10. The organic light-emitting device of claim 6, wherein the triazine-based compound is selected from the group consisting of 2,4,6-tris(diarylamino)-1,3,5-triazine, 2,4,6-tris(diphenylamino)-1,3,5-tirazine, 2,4,6-tricarbazolo-1,3,5-triazine, 2,4,6-tris(N-phenyl-2-naphthylamino)-1,3,5-triazine, 2,4,6-tris(N-phenyl-1-naphthylamino)1,3,5-triazine, and 2,4,6-trisbiphenyl-1,3,5-triazine, and the triazole-based compound is 3-phenyl-4-(1′-naphthyl)-5-phenyl-1,2,4-triazole.

11. The organic light-emitting device of claim 6, wherein the spirofluorene-based compound is selected from the group consisting of phenylspirofluorene, biphenylspirofluorene and methylspirofluorene.

12. The organic light-emitting device of claim 1, wherein the first dopant and the second dopant are each independently selected from the group consisting of bisthienylpyridine acetylacetonate iridium, bis(benzothienylpyridine)acetylacetonate iridium, bis(2-phenylbenzothiazole)acetylacetonate iridium, bis(1-phenylisoquinoline)iridium acetylacetonate, tris(1-phenylisoquinoline)iridium, tris(2-phenylpyridine)iridium, and a combination thereof.

13. An organic light-emitting device, comprising:
a substrate;
a pair of electrodes on the substrate, the pair of electrodes comprising a hole injection electrode and an electron injection electrode; and
an emission layer interposed between the pair of electrodes, the emission layer comprising at least one of a red emission layer patterned in a red light-emitting region and a green emission layer patterned in a green light-emitting region, and a blue emission layer formed as a common layer covering said at least one of the red emission layer and the green emission layer and a blue light-emitting region, the blue emission layer positioned between the electron injection electrode and said at least one of the red emission layer and the green emission layer;
wherein, when the emission layer comprises the red emission layer, the red emission layer comprises a first host and a first dopant, a highest occupied molecular orbital (HOMO) level of the first host is lower than a highest occupied molecular orbital (HOMO) level of the first dopant by at least 0.1 eV, and a lowest occupied molecular orbital (LUMO) level of the first host is lower than a lowest occupied molecular orbital (LUMO) level of the first dopant by at least 0.1 eV; and
when the emission layer comprises the green emission layer, the green emission layer comprises a second host and a second dopant, a highest occupied molecular orbital (HOMO) level of the second host is lower than a highest occupied molecular orbital (HOMO) level of the second dopant by at least 0.1 eV, and a lowest occupied molecular orbital (LUMO) level of the second host is lower than a lowest occupied molecular orbital (LUMO) level of the second dopant by at least 0.1 eV.

14. The organic light-emitting device of claim 13, wherein the first host and the second host are each independently selected from the group consisting of a carbazole-based compound, an organic metal complex, an oxadiazole-based compound, a phenanthroline-based compound, a triazine-based compound, a triazole-based compound, a spirofluorene-based compound, TPBi, and a combination thereof: and
the first dopant and the second dopant are each independently selected from the group consisting of bisthienylpyridine acetylacetonate iridium, bis(benzothienylpyridine)acetylacetonate iridium, bis(2-phenylbenzothiazole)acetylacetonate iridium, bis(1-phenylisoquinoline)iridium acetylacetonate, tris(1-phenylisoquinoline)iridium, tris(2-phenylpyridine)iridium, and a combination thereof.

15. An organic light-emitting device, comprising:
a substrate;
a pair of electrodes on the substrate, the pair of electrodes comprising a hole injection electrode and an electron injection electrode; and
an emission layer interposed between the pair of electrodes, the emission layer comprising:
a red emission layer patterned in a red light-emitting region, the red emission layer comprising a first host and a first dopant, a highest occupied molecular orbital (HOMO) level of the first host being lower than a highest occupied molecular orbital (HOMO) level of the first dopant, a lowest occupied molecular orbital (LUMO) level of the first host being lower than a lowest occupied molecular orbital (LUMO) level of the first dopant;
a green emission layer patterned in a green light-emitting region, the green emission layer comprising a second host and a second dopant, a highest occupied molecular orbital (HOMO) level of the second host being lower than a highest occupied molecular orbital (HOMO) level of the second dopant, and a lowest occupied molecular orbital (LUMO) level of the second host being lower than a lowest occupied molecular orbital (LUMO) level of the second dopant; and
a blue emission layer formed as a common layer covering the red emission layer and the green emission layer and a blue light-emitting region.

16. The organic light-emitting device of claim 15, wherein a difference between the HOMO level of the first host and the HOMO level of the first dopant is at least 0.1 eV, and a difference between the LUMO level of the first host and the LUMO level of the first dopant is at least 0.1 eV.

17. The organic light-emitting device of claim 15, wherein a difference between the HOMO level of the second host and the HOMO level of the second dopant is at least 0.1 eV, and a difference between the LUMO level of the second host and the LUMO level of the second dopant is at least 0.1 eV.

18. The organic light-emitting device of claim 15, wherein the first host and the second host are independently chosen from materials having the HOMO level of −6.5 eV to −5.0 eV and the LUMO level of −3.5 eV to −2.0 eV, and
the first dopant and the second dopant are independently chosen from materials having the HOMO level of −6.0 eV to −4.0 eV, and the LUMO level of −3.0 eV to −1.0 eV.

19. The organic light-emitting device of claim 15, wherein the first host and the second host are each independently selected from the group consisting of a carbazole-based compound, an organic metal complex, an oxadiazole-based compound, a phenanthroline-based compound, a triazine-based compound, a triazole-based compound, a spirofluorene-based compound, TPBi, and a combination thereof: and
the first dopant and the second dopant are each independently selected from the group consisting of bisthienylpyridine acetylacetonate iridium, bis(benzothienylpyridine)acetylacetonate iridium, bis(2-phenylbenzothiazole)acetylacetonate iridium, bis(1-phenylisoquinoline)iridium acetylacetonate, tris(1-phenylisoquinoline)iridium, tris(2-phenylpyridine)iridium, and a combination thereof

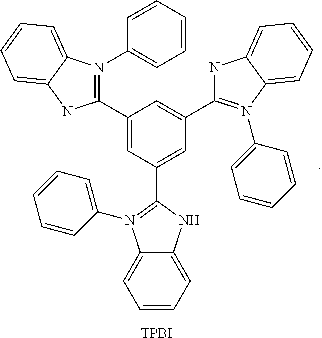

20. The organic light-emitting device of claim 18, wherein the carbazole-based compound is selected from the group consisting of 1,3,5-tricarbazolylbenzene, 4,4′-biscarbazolylbiphenyl(CBP), m-biscarbazolylphenyl, 4,4′-biscarbazolyl-2,2′-dimethylbiphenyl, 4,4′,4″-tri(N-carbazolyl)triphenylamine, 1,3,5-tri(2-carbazolyl phenyl)benzene, 1,3,5-tris(2-carbazolyl-5-methoxyphenyl)benzene, and bis(4-carbazolyl phenyl)silane;
the organic metal complex is selected from the group consisting of bis(8-hydroxyquinolato)biphenoxy metal, bis(8-hydroxyquinolato)phenoxy metal, bis(2-methyl-8-hydroxyquinolato)biphenoxy metal, bis(2-methyl-8-hydroxyquinolato)phenoxy metal, bis(2-methyl-8-quinolinolato)(para-phenyl-phenolato)metal, bis(2-(2-hydroxyphenyl)quinolato)metal, and a combination thereof, and the metal is aluminum (Al), zinc (Zn), beryllium (Be) or gallium (Ga);
the oxadiazole-based compound is (4-biphenylyl)-5-(4-tertbutylphenyl)-1,3,4-oxadiazole;
the phenanthroline-based compound is 2,9-dimethyl-4,7-diphenyl-9,10-phenanthroline;
the triazine-based compound is selected from the group consisting of 2,4,6-tris(diarylamino)-1,3,5-triazine, 2,4,6-tris(diphenylamino)-1,3,5-tirazine, 2,4,6-tricarbazolo-1,3,5-triazine, 2,4,6-tris(N-phenyl-2-naphthylamino)-1,3,5-triazine, 2,4,6-tris(N-phenyl-1-naphthylamino)1,3,5-triazine, and 2,4,6-trisbiphenyl-1,3,5-triazine;
the triazole-based compound is 3-phenyl-4-(1-naphthyl)-5-phenyl-1,2,4-triazole; and
the spirofluorene-based compound is selected from the group consisting of phenylspirofluorene, biphenylspirofluorene and methylspirofluorene.
